(19) United States
(12) Patent Application Publication
(10) Pub. No.: US 2020/0006712 A1
(43) Pub. Date: Jan. 2, 2020

(54) METHOD FOR MANUFACTURING DISPLAY PANEL AND APPARATUS FOR MANUFACTURING DISPLAY PANEL

(71) Applicant: Sharp Kabushiki Kaisha, Sakai City, Osaka (JP)

(72) Inventors: Kohji SAKIKAWA, Sakai City (JP); Manabu NIBOSHI, Sakai City (JP)

(21) Appl. No.: 16/473,283

(22) PCT Filed: Sep. 27, 2017
(86) PCT No.: PCT/JP2017/034939

§ 371 Date: Jun. 25, 2019

(51) Int. Cl. H01L 51/56; H01L 21/66

(52) U.S. Cl. CPC H01L 51/56; G09G 2320/0295; H01L 22/12

(57) ABSTRACT

For the purpose of manufacturing display panels to be manufactured during the manufacturing process in the same lot with the inspection process further shortened while luminance unevenness between the display panels reduced, provided is a method for manufacturing a display panel, the method including an inspection mother substrate manufacturing step of manufacturing an inspection mother substrate including a plurality of inspection elements, a manufacturing mother substrate manufacturing step of manufacturing a plurality of manufacturing mother substrates including a plurality of display panels including a light emitting element, a measurement step of measuring distribution of light emission intensity from the plurality of inspection elements, a calculation step of calculating a correction value of a light emission voltage for each of the display panels according to the distribution, and a correction step of correcting a light emission voltage of the light emitting element of each of the display panels based on the correction value.

### TECHNICAL FIELD

The disclosure relates to a manufacturing method of a display panel including a light emitting element and a manufacturing apparatus of the display panel.

### BACKGROUND ART

PTL 1 describes an inspection method of an organic EL panel for manufacturing an organic EL panel with reduced unevenness of light emission intensity between organic EL elements in the panel.

### CITATION LIST

### Patent Literature

PTL 1: JP 2010-134169 A (published on Jun. 17, 2010)

### SUMMARY

### Technical Problem

When a plurality of display panels are formed on one mother substrate in one slot during manufacturing a display panel, unevenness in light emission intensity may occur for each panel due to the film thickness difference between display panels and the like on the same mother substrate. Such luminance unevenness tends to occur at the same distribution for each mother substrate included in the same lot.

In the inspection method of luminance unevenness described in PTL 1, the measurement of luminance unevenness is required for each panel even when the above luminance unevenness is inspected.

### Solution to Problem

In order to solve the above problem, a method for manufacturing a display panel of the present application includes:

an inspection mother substrate manufacturing step of manufacturing an inspection mother substrate including a plurality of inspection elements;

a manufacturing mother substrate manufacturing step of manufacturing a plurality of manufacturing mother substrates including a plurality of display panels including a light emitting element;

a measurement step of measuring distribution of light emission intensity from the plurality of inspection elements;

a calculation step of calculating a correction value of a light emission voltage for each of the display panels according to the distribution; and

a correction step of correcting the light emission voltage of the light emitting element of each of the display panels based on the correction value.

In addition, in order to solve the above problem, the apparatus for manufacturing a display panel of the present application includes:

a substrate manufacturing device configured to manufacture an inspection mother substrate including

a plurality of inspection elements, and

a plurality of manufacturing mother substrates including a plurality of display panels including a light emitting element;

a measuring device configured to measure a distribution of light emission intensity from the plurality of inspection elements; and

a storage device configured to calculate a correction value of a light emission voltage of the light emitting element for each of the display panels corresponding to the distribution, to store the correction value, and to record the correction value into each of the display panels.

### Advantageous Effects of Disclosure

According to the above configuration, it is possible to provide a method for manufacturing a display panel in which, regarding the display panels to be manufactured during the manufacturing process in the same lot, the inspection process can be further shortened while luminance unevenness between the display panels is reduced.

### BRIEF DESCRIPTION OF DRAWINGS

FIG. 1 is a flowchart illustrating a manufacturing method of an organic EL panel according to a first embodiment.

FIG. 2 is a schematic diagram illustrating an organic EL panel to be manufactured in the first embodiment and a manufacturing apparatus of the organic EL panel.

FIG. 3 is a schematic top view illustrating an inspection mother substrate according to the first embodiment.

FIGS. 4A and 4B are a schematic diagram illustrating an inspection element according to the first embodiment.

FIG. 5 is a schematic top view illustrating the organic EL panel according to the first embodiment.

FIGS. 6A and 6B are a schematic top view illustrating a positional relationship between the inspection element of the inspection mother substrate and the organic EL panel of the panel manufacturing mother substrate according to the first embodiment.

FIG. 7 is a schematic diagram illustrating an organic EL panel to be manufactured in a second embodiment and a manufacturing apparatus of the organic EL panel.

FIG. 8 is a flowchart illustrating a manufacturing method of an organic EL panel according to a third embodiment.

FIG. 9 is a schematic diagram illustrating an organic EL panel to be manufactured in the third embodiment and a manufacturing apparatus of the organic EL panel.

FIGS. 10A and 10B are a transmissive top view for illustrating a positional relationship between the organic EL panel to be manufactured and the corresponding inspection element in the third embodiment.

FIG. 11 is a schematic diagram illustrating an organic EL panel to be manufactured and a manufacturing apparatus of the organic EL panel in a modified example.

### DESCRIPTION OF EMBODIMENTS

### First Embodiment

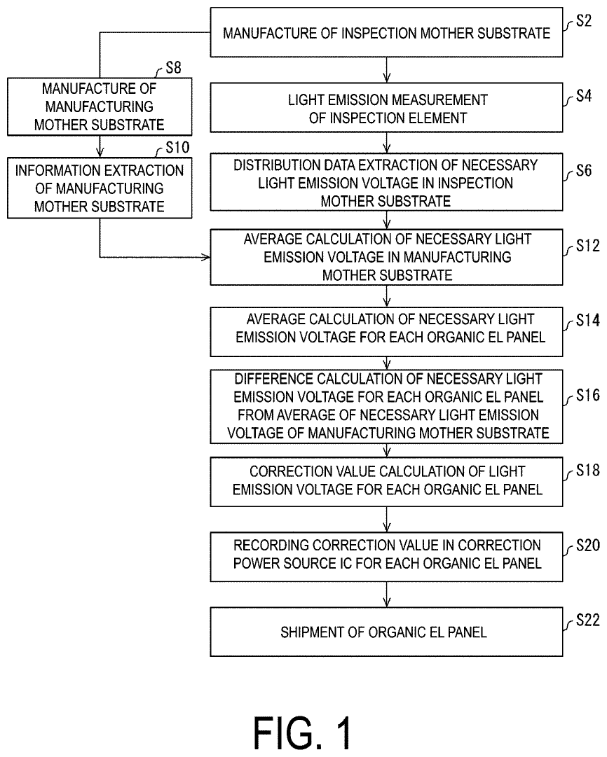

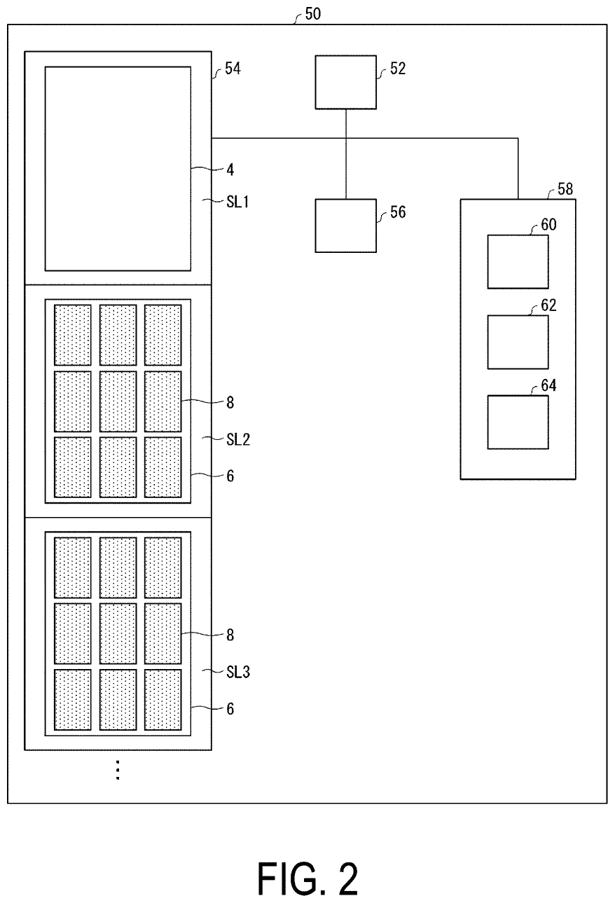

With reference to FIG. 1 and FIG. 2 to FIG. 6B, the manufacturing method and manufacturing apparatus of the organic EL panel (display panel) according to the present embodiment will be described. FIG. 1 is a flowchart illustrating a manufacturing method of the organic EL panel according to the present embodiment. FIG. 2 is a diagram for illustrating the organic EL panel manufactured in the present embodiment and the manufacturing apparatus of the organic EL panel.

In the present embodiment, a method for manufacturing a plurality of organic EL panels 8 to be formed on the manufacturing mother substrate 6 by using the manufacturing apparatus 50 of the organic EL panel illustrated in FIG. 2 will be described. The manufacturing apparatus 50 of the organic EL panel includes a controller 52, a substrate manufacturing device 54, a measuring device 56, and a storage device 58. The storage device 58 includes a distribution storage device 60, a substrate information storage device 62, and a correction value storage device 64.

The controller 52 controls each of the substrate manufacturing device 54, the measuring device 56, and the storage device 58.

The substrate manufacturing device 54 includes a plurality of slots. In the present embodiment, the substrate manufacturing device 54 manufactures an inspection mother substrate 4 in a first slot SL1. In addition, the substrate manufacturing device 54 manufactures manufacturing mother substrates 6 one by one in each of the slots after the inspection mother substrate 4 is manufactured in the first slot SL1.

FIG. 2 illustrates the first slot SL1, the second slot SL2, and the third slot SL3. However, the disclosure is not limited to this, and the substrate manufacturing device 54 may include more slots. In the following, assume that one group of manufacturing mother substrates 6 to be manufactured at a time by the substrate manufacturing device 54 are included in the same manufacture lot.

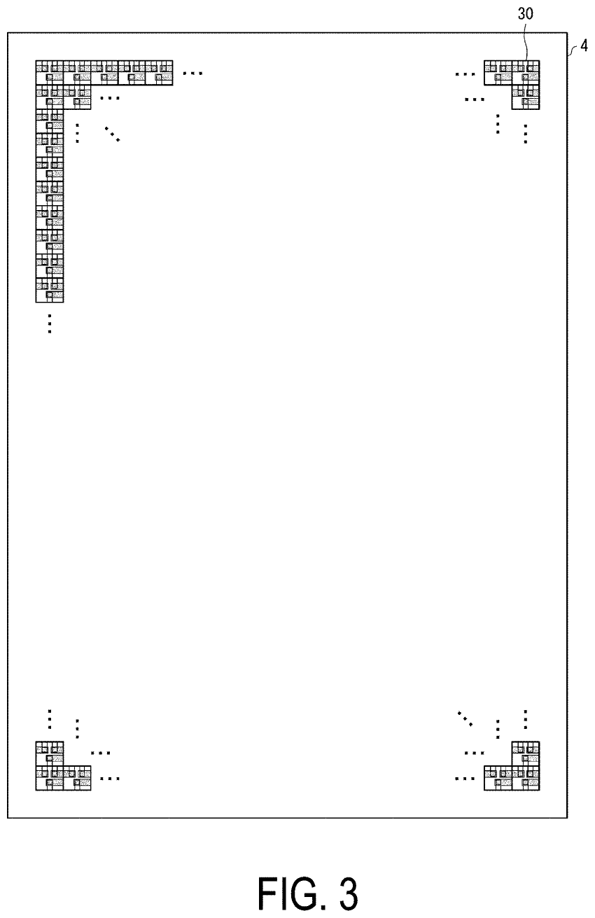

In the manufacturing method of an organic EL panel according to the present embodiment, first, the inspection mother substrate 4 is manufactured by the substrate manufacturing device 54 (step S2). As illustrated in FIG. 3, the inspection mother substrate 4 includes a plurality of inspection elements 30 formed in a matrix shape on a mother glass substrate.

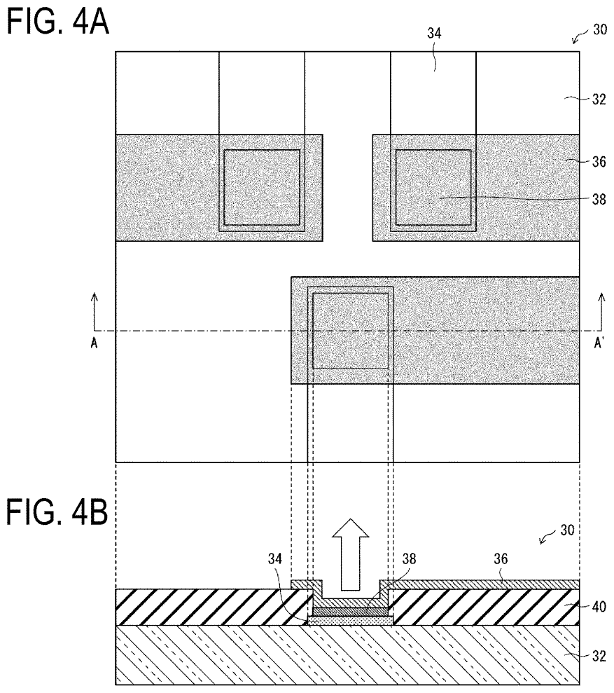

FIGS. 4A and 4B are schematic diagrams illustrating an inspection element 30 in detail, FIG. 4A is a schematic diagram illustrating the upper face, and FIG. 4B is a schematic diagram illustrating a cross section taken along the line A-A′ in FIG. 4A. As illustrated in FIGS. 4A and 4B, the inspection element 30 includes a glass substrate 32, a reflective electrode 34, a transmissive electrode 36, a light-emitting layer 38, and an insulating layer 40. It should be noted that regarding FIG. 4A, the illustration of the insulating layer 40 is omitted.

In the inspection element 30, a plurality of sub-elements are formed on the glass substrate 32. Each of the sub-elements includes a reflective electrode 34, a transmissive electrode 36, and a light-emitting layer 38 including an organic EL. Each of the electrode and light-emitting layer of the sub-element is insulated by the insulating layer 40.

Applying an appropriate potential difference between the reflective electrode 34 and the transmissive electrode 36 of one sub-element causes the light-emitting layer 38 to emit light. At this time, since the light from the light-emitting layer 38 is reflected by the reflective electrode 34 and transmitted through the transmissive electrode 36, the light travels toward the transmissive electrode 36 as indicated by an arrow in FIG. 4B. The light emitted by the light-emitting layer 38 of each of the sub-elements corresponds to the light emitted by a corresponding one of a plurality of subpicture elements in the light emitting element of the organic EL panel 8.

The configuration included in the organic EL panel 8 of the manufacturing mother substrate 6 above the light emitting element is formed above the inspection element 30 of the inspection mother substrate 4 by the same process as in the manufacture of the manufacturing mother substrate 6. Therefore, above the inspection element 30 of the inspection mother substrate 4, a configuration corresponding to the configuration above the light emitting element of the manufacturing mother substrate 6 is provided. For example, the organic EL panel 8 may include a sealing film above the light emitting element, in which case a sealing film is similarly formed also above the inspection element 30 of the inspection mother substrate 4.

At this time, in the manufacturing process in the same lot, the thickness unevenness of films including a sealing film tends to occur similarly for each mother substrate in a corresponding slot. Therefore, in the manufacturing process in the same lot, when thickness unevenness occurs in the manufacture of the manufacturing mother substrate 6, it is thought that similar thickness unevenness occurs also in the sealing film in the inspection mother substrate 4.

With reference to FIG. 1 again, after the inspection mother substrate manufacturing process, the inspection element 30 of the inspection mother substrate 4 is individually light-emitted, its light emission intensity is measured (step S4), and the distribution of the light emission intensity of the inspection element 30 on the inspection mother substrate 4 is determined. The above measurement is performed by the measuring device 56. The measuring device 56 may employ various known light intensity measuring devices in the related art.

For example, when the inspection mother substrate 4 has thickness unevenness, the light emission intensity from the inspection element 30 is relatively low at the position where the sealing film is thick, and the light emission intensity from the inspection element 30 is relatively high at the position where the sealing film is thin. The thickness unevenness is also reflected in the manufacturing mother substrate 6. Therefore, applying the same potential difference to the light emitting element to emit light between the organic EL panels 8 on the manufacturing mother substrate 6 reflects the luminance unevenness due to the thickness unevenness.

Therefore, in order that the luminance unevenness due to the film thickness between the organic EL panels 8 on the manufacturing mother substrate 6 is eliminated, the light emission voltage needed to cause the light emitting element to emit light has only to be corrected for each organic EL panel 8. Therefore, in the present embodiment, from the measurement of the light emission intensity of the inspection element 30 described above, the distribution data of the necessary light emission voltage on the inspection mother substrate 4 is calculated (step S6). The distribution data of the necessary light emission voltage is recorded in the distribution storage device 60 of the storage device 58.

The distribution data is determined from the relationship between the film thickness distribution of the manufacturing mother substrate 6 and the light emission intensity of the inspection element 30. For example, the distribution of the film thickness of the previously manufactured inspection mother substrate 4 is measured, and in addition to this, the distribution of the light emission intensity of the inspection element 30 on the inspection mother substrate 4 is determined. Thus, the relationship between the film thickness of the inspection mother substrate 4 and the light emission intensity of the inspection element 30 can be determined.

Then, experimentally producing the manufacturing mother substrate 6, and determining the distribution of the light emission intensity of the light emitting element thereof allows the relationship between the light emission intensity of the inspection element 30 of the inspection mother substrate 4 and the light emission intensity of the light emitting element of the manufacturing mother substrate 6 to be calculated. Thus, from the light emission intensity of the inspection element 30 of the inspection mother substrate 4, the necessary voltage for obtaining sufficient light emission from the light emitting element of the organic EL panel 8 of the actual manufacturing mother substrate 6 can be calculated.

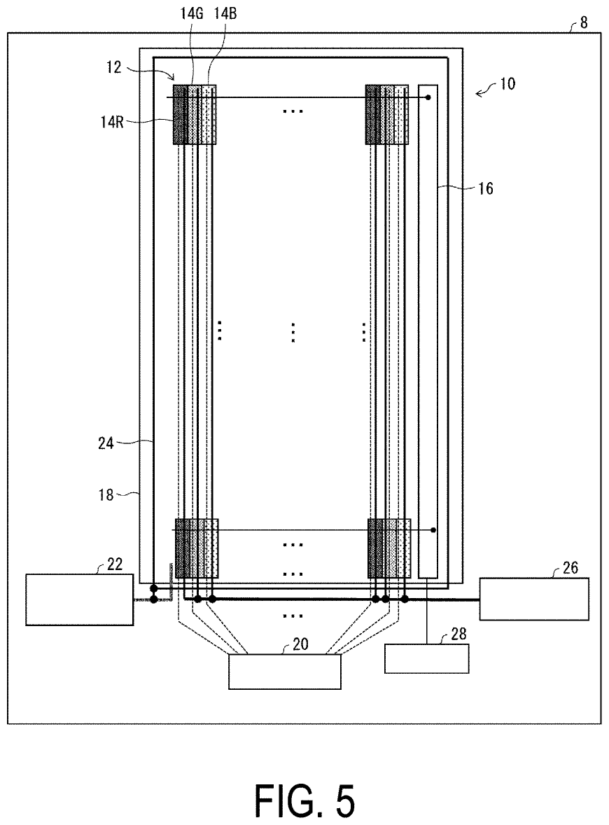

While the measurement process is performed, a plurality of manufacturing mother substrates 6 are carried and a plurality of organic EL panels 8 are manufactured on the manufacturing mother substrate 6 (step S8). FIG. 5 illustrates an example of the organic EL panel 8 according to the present embodiment. FIG. 5 is a transmission top view of the organic EL panel 8 according to the present embodiment. It should be noted that in FIG. 5, illustration of the lower electrode connected to each light emitting element is omitted.

The organic EL panel 8 includes an element circuit unit 10. The element circuit unit 10 includes a plurality of light emitting elements 12 formed in a matrix shape. Each of the light emitting elements 12 includes a plurality of subpicture elements 14R, 14G, and 14B. Each of the subpicture elements 14R, 14G, and 14B is formed on a corresponding one of the lower electrodes connected to a corresponding one of the thin film transistors (TFT) formed in a matrix shape on the manufacturing mother substrate 6. The gate electrode of the TFT in each light emitting element 12 is connected to the gate driver 16. The element circuit unit 10 further includes an upper electrode 18 being a whole surface electrode above the light emitting element 12.

In the present embodiment, outside the element circuit unit 10, the organic EL panel 8 includes a source driver 20, an upper electrode power source 22, a lower electrode power source 26, and a control signal transmission unit 28. The source driver 20 is connected to a source electrode of the TFT in each light emitting element 12. The upper electrode power source 22 is connected to the bus line 24 on the TFT side of the upper electrode 18. The lower electrode power source 26 is connected to the lower electrode in each light emitting element 12. The control signal transmission unit 28 transmits a drive signal to the gate driver 16.

In each of the subpicture elements 14R, 14G, and 14B, an organic layer may be individually formed for each subpicture element, and a color filter may be formed for each subpicture element on the organic layer for emitting white light. In addition, the gate driver 16 and the source driver 20 are not limited to the present configuration, and the arrangement of the exterior and interior may be exchanged, or may be arranged on both sides. It should be noted that the drive of the picture element, such as the drive method of the picture element and the signal from the control signal transmission unit 28, may be performed by using a known technique in the related art.

With reference to FIG. 1 again, in the manufacturing mother substrate manufacturing process, for each manufacturing mother substrate 6, the shape and arrangement of the manufacturing mother substrate 6 are recorded in the substrate information storage device 62 of the storage device 58. In addition, the shape and arrangement of the organic EL panel 8 in each manufacturing mother substrate 6 is also recorded in the substrate information storage device 62. Thus, the substrate information about the manufacturing mother substrate 6 is extracted (step S10).

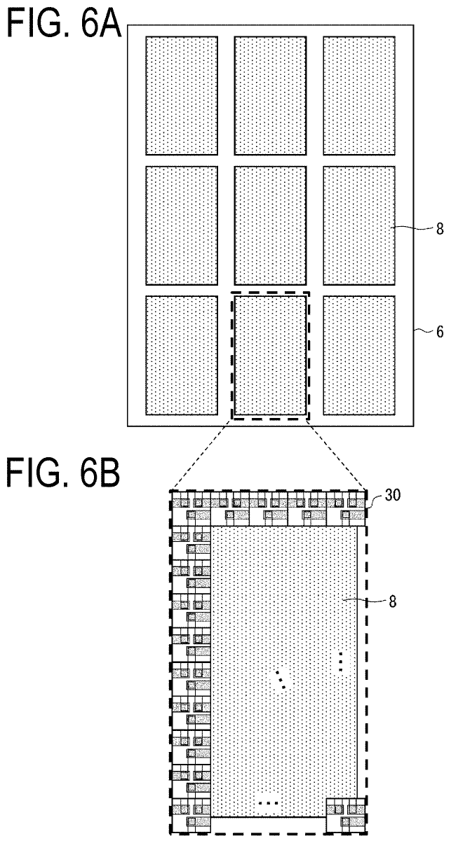

Then, the positions of the inspection element 30 of the inspection mother substrate 4 and the organic EL panel 8 on the manufacturing mother substrate 6 are compared based on the above-described substrate information. Then, based on the comparison, calculation processes of calculating the average of necessary light emission voltages in the manufacturing mother substrate 6 (step S12) and of calculating the average of the necessary light emission voltages for each organic EL panel 8 on the manufacturing mother substrate 6 (step S14) are performed. Steps S12 and S14 will be described in detail with reference to FIGS. 6A and 6B.

FIG. 6A illustrates an upper face of the manufacturing mother substrate 6, and FIG. 6B is an enlarged top view of the broken line portion in FIG. 6A. FIG. 6B illustrates a positional relationship between the position of the organic EL panel 8 in the manufacturing mother substrate 6 and the inspection element 30 of the inspection mother substrate 4 corresponding to the position.

The inspection mother substrate 4 includes inspection elements 30 formed in a matrix shape. Here, consider virtually overlapping the first slot SL1 on which the inspection mother substrate 4 is manufactured and each of the slots in which the manufacturing mother substrates 6 are manufactured. In this case, the inspection element 30 of the inspection mother substrate 4 formed at a position overlapping with the manufacturing mother substrate 6 is identified. In addition, the inspection element 30 of the inspection mother substrate 4 formed at a position overlapping with the organic EL panel 8 on the manufacturing mother substrate 6 can be identified as illustrated in FIG. 6B.

In steps S12 and S14, the number of the inspection elements 30 corresponding to the above-described manufacturing mother substrate 6 and the organic EL panel 8 and the distribution of the light emission intensity from the inspection elements 30 thereof are extracted. In this way, from the extracted number and the light emission intensity distribution, an average of necessary light emission voltages for each corresponding manufacturing mother substrate 6 and organic EL panel 8 is calculated.

Then, a difference between the average of the necessary light emission voltages calculated from the whole manufacturing mother substrate 6 and the average of the necessary light emission voltages calculated for each organic EL panel 8 is determined for each organic EL panel 8 (step S16).

For example, when the film thickness in the corresponding organic EL panel 8 is relatively thin, the average of the necessary light emission voltages for each organic EL panel 8 is lower than the average of the necessary light emission voltages in the whole manufacturing mother substrate 6. On the other hand, when the film thickness in the corresponding organic EL panel 8 is relatively thick, the average of the necessary light emission voltages for each organic EL panel 8 is higher than the average of the necessary light emission voltages in the whole manufacturing mother substrate 6.

Then, from the calculated difference, a correction value of the light emission voltage for each organic EL panel 8 is calculated (step S18). Each of the calculated correction values is associated with the information on the corresponding organic EL panel 8 and recorded in the correction value storage device 64 of the storage device 58. Then, the correction value stored in the correction value storage device 64 is recorded in the correction power source IC for each organic EL panel 8 (step S20).

For example, when the average of the necessary light emission voltages for each organic EL panel 8 is lower than the average of the necessary light emission voltages in the whole manufacturing mother substrate 6, the correction of lowering the light emission voltage by the amount of the difference is recorded in the correction power source IC. On the other hand, when the average of the necessary light emission voltages for each organic EL panel 8 is higher than the average of the necessary light emission voltages in the whole manufacturing mother substrate 6, the correction of increasing the light emission voltage by the amount of the difference is recorded in the correction power source IC.

The above correction determines an appropriate light emission voltage for each organic EL panel 8 and reduces the luminance unevenness between organic EL panels 8 in the same manufacturing mother substrate 6. It should be noted that the above-described correction value may be recorded in the upper electrode power source 22 connected to the upper electrode 18 being the whole surface electrode.

Thus, the correction process of the organic EL panel 8 is completed. Finally, through the partition of the manufacturing mother substrate 6 and the like, the organic EL panel 8 is shipped (step S22), and the manufacture of the organic EL panel 8 is completed.

In the manufacturing method described above, the luminance unevenness between the organic EL panels 8 of the manufacturing mother substrate 6 can be corrected based on the measured luminance unevenness of the inspection mother substrate 4.

In addition, since the inspection mother substrate 4 and the manufacturing mother substrate 6 are manufactured in the same lot, the luminance unevenness occurring in the inspection mother substrate 4 tends to be similarly reflected in all the manufacturing mother substrates 6. Therefore, correction values of all the organic EL panels 8 can be determined based on the measurement of the light emission intensity of the inspection mother substrate 4 without the light emission intensity being measured for each organic EL panel 8 manufactured at a time. Therefore, it is possible to more easily perform the inspection while reducing the luminance unevenness between the organic EL panels 8.

It should be noted that in the present embodiment, the substrate information thereof may be recorded each time the manufacturing mother substrate 6 is manufactured. However, in the present embodiment, the same manufacturing mother substrate 6 and organic EL panel 8 are manufactured in each of all the slots. Therefore, the substrate information extracted from the manufacturing mother substrate 6 of the second slot SL2 may be caused to correspond to the manufacturing mother substrates 6 after the second slot SL2. In this case, there is no need to extract the substrate information for each manufacturing mother substrate 6, and the same correction may be applied to all the manufacturing mother substrates 6. Thus, it is possible to more easily manufacture the organic EL panel.

It should be noted that the sub-element of the inspection element 30 emits light of a color corresponding to each of the subpicture elements 14R, 14G, and 14B of the light emitting element 12. Therefore, performing the measurement described above for each sub-element of the inspection element 30 allows the correction value for each subpicture element to be determined. Therefore, in the present embodiment, inspection and correction can be performed also on the luminance unevenness of each subpicture element between the organic EL panels 8.

In the present embodiment, a method and an apparatus for manufacturing a plurality of organic EL panels 8 in the manufacturing mother substrate 6 are described as an example. However, also in the manufacturing method and manufacturing apparatus of the display panel including the light emitting element containing materials different from the organic EL, such as the quantum dot and the phosphor, the configuration of the present embodiment can be applied.

### Second Embodiment

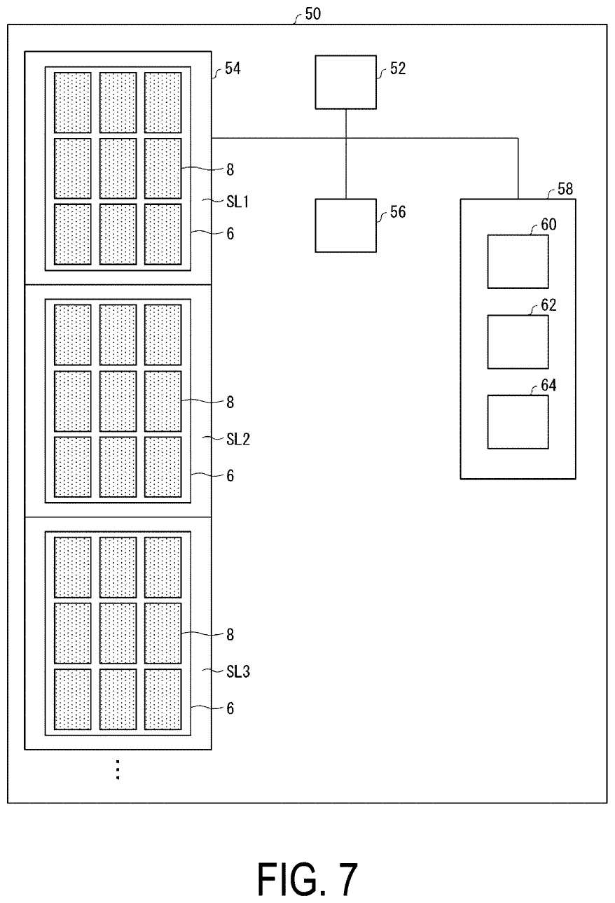

FIG. 7 is a diagram for illustrating a manufacturing apparatus 50 of an organic EL panel according to the present embodiment. The manufacturing method of the organic EL panel 8 according to the present embodiment differs from that of the previous embodiment in that the manufacturing mother substrate 6 is manufactured also in the first slot SL1 of the substrate manufacturing device 54 and the measurement of the light emission intensity is performed by using the manufacturing mother substrate 6.

With reference to FIG. 1, the manufacturing method of the organic EL panel 8 in the present embodiment will be described. First, in step S2, the manufacturing mother substrate 6 is manufactured in the first slot SL1 instead of the inspection mother substrate 4. Then, in step S4, the light emitting element 12 of the organic EL panel 8 is light-emitted instead of the inspection element 30, and the light emission measurement described above is performed. On this occasion, when the light emitting element 12 is smaller than the inspection element 30, simultaneously lighting a plurality of light emitting elements 12 may be regarded as the light emission of one of the inspection elements 30, and measurement may be performed.

Then, the average of the necessary light emission voltages of the whole manufacturing mother substrate 6 is calculated. On this occasion, at the same time, the average of the necessary light emission voltages for each organic EL panel 8 may be calculated. In this case, with the plurality of light emitting elements 12 regarded as the light emission of one of the inspection elements 30 as one of the inspection elements 30, the number is counted, and the average is calculated.

From the difference between the average of the necessary light emission voltages for each organic EL panel 8 described above and the average of the necessary light emission voltages of the whole manufacturing mother substrate 6, the correction value of the light emission voltage for each organic EL panel 8 is calculated. Thereafter, in the correction process, as in the previous embodiment, recording the correction value for each manufactured organic EL panel 8 allows the luminance unevenness for each organic EL panel 8 to be corrected.

In the present embodiment, the measurement in the measurement process is performed by using the manufacturing mother substrate 6. Therefore, there is no need to design and manufacture the inspection mother substrate 4, and the organic EL panel 8 may be more easily manufactured.

It should be noted that in the present embodiment, when the manufacturing mother substrate 6 and the organic EL panel 8 manufactured in the first slot SL1 and the manufacturing mother substrate 6 and the organic EL panel 8 manufactured in the slot after the first slot SL1 are the same, the correction value calculated in the first slot SL1 can be applied to the organic EL panel 8 in the slot after the first slot SL1. Therefore, the extraction of the substrate information on the manufacturing mother substrate 6 and the organic EL panel 8 may be omitted.

### Third Embodiment

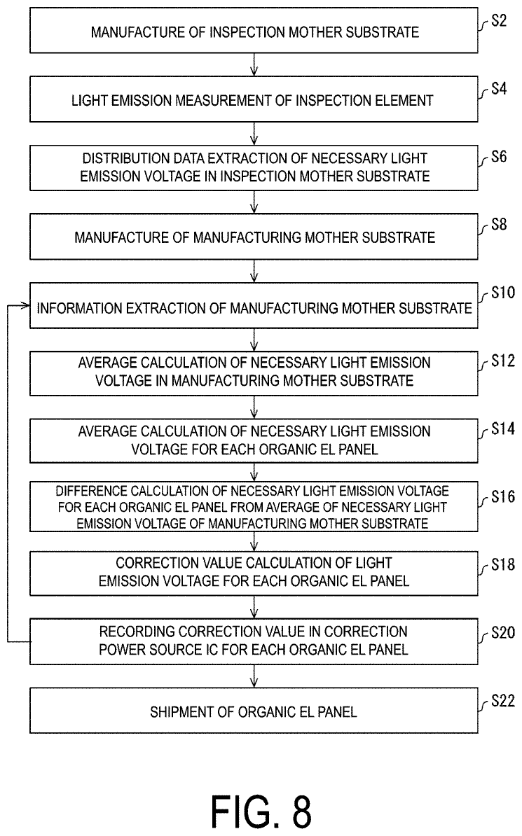

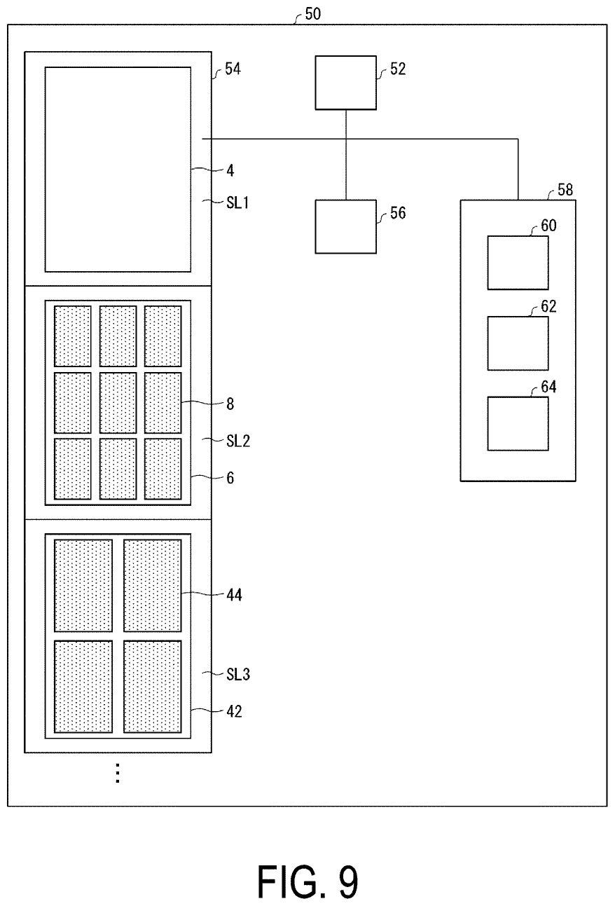

With reference to FIG. 8 to FIG. 10B, the manufacturing method of the organic EL panel according to the present embodiment will be described. FIG. 8 is a flowchart illustrating the manufacturing method of an organic EL panel according to the present embodiment. FIG. 9 is a diagram for illustrating a manufacturing apparatus 50 of an organic EL panel according to the present embodiment.

First, in steps S2 to S6, as in the previous embodiment, the inspection mother substrate 4 is manufactured, and the distribution of the necessary light emission voltages in the inspection mother substrate 4 is extracted. Then, in step S8, the manufacturing mother substrate and the organic EL panel are manufactured.

In this case, unlike in the above embodiment, in the present embodiment, in at least one slot, the manufacturing mother substrate and organic EL panel to be manufactured are different in configuration from the manufacturing mother substrate and organic EL panel in other slots.

With reference to FIG. 9, in the second slot SL2, it is illustrated that the organic EL panels 8 are formed on the manufacturing mother substrate 6. On the other hand, in the third slot SL3, it is illustrated that organic EL panels 44 different from the organic EL panels 8 are formed on a manufacturing mother substrate 42 different from the manufacturing mother substrate 6.

Thus, when manufacturing mother substrates and organic EL panels of different shapes are manufactured in slots, for each slot, the number of the inspection elements 30 and the distribution of the light emission intensity corresponding to the manufacturing mother substrate and the organic EL panel have only to be extracted, and the correction value has only to be determined. Therefore, in the present embodiment, every time the manufacturing mother substrate 6 is manufactured, the substrate information in the slot is extracted, and an appropriate correction value is calculated and recorded in the organic EL panel.

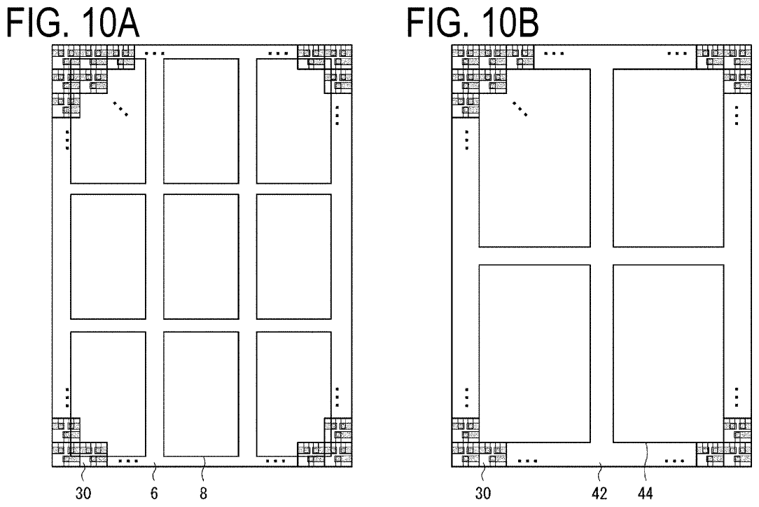

Extraction of substrate information and calculation of correction values in the present embodiment will be described in detail with reference to FIGS. 10A and 10B. FIGS. 10A and 10B are diagrams in which the first slot SL1 and each of the second slot SL2 and third slot SL 3 are virtually overlapped, and the positional relationships between the inspection mother substrate 4 and each of the manufacturing mother substrate 6 and manufacturing mother substrate 42 are compared.

FIG. 10A is a diagram in which the inspection mother substrate 4 and the manufacturing mother substrate 6 are overlapped and the positional relation is compared. Since the inspection element 30 is formed in the inspection mother substrate 4 in a matrix shape, as described above, in the inspection mother substrate 4, the inspection element 30 is formed also at the position corresponding to each of the organic EL panels 8.

From this, based on the substrate information obtained in the manufacturing mother substrate manufacturing process, the inspection element 30 overlapping with the manufacturing mother substrate 6 and each of the organic EL panels 8 is identified. Therefore, based on the necessary light emission voltage obtained from the identified inspection element 30, each of the averages of the necessary light emission voltages in the manufacturing mother substrate 6 and the corresponding one of the organic EL panels 8 are calculated. The difference between the average of the necessary light emission voltages in the calculated manufacturing mother substrate 6 and the average of the necessary light emission voltages in each of the organic EL panels 8 is the correction value of the light emission voltage in the corresponding one of the organic EL panels 8.

FIG. 10B is a diagram in which the inspection mother substrate 4 and the manufacturing mother substrate 42 are overlapped and the positional relation is compared. The shape and arrangement of each organic EL panel 44 in the manufacturing mother substrate 42 is different from the shape and arrangement of each organic EL panel 8 in the manufacturing mother substrate 6. That is, the inspection element 30 overlapping with the manufacturing mother substrate 42 and each of the organic EL panels 44 is different from the inspection element 30 overlapping with the manufacturing mother substrate 6 and each of the organic EL panels 8.

Therefore, based on the substrate information obtained in the manufacturing mother substrate manufacturing process, an inspection element 30 overlapping with the manufacturing mother substrate 42 and each of the organic EL panels 44 is newly identified. Therefore, in the same manner as described above, the correction value of the light emission voltage in each organic EL panel 44 is calculated.

The calculated correction values are associated with the information about the respective organic EL panels, recorded in the correction value storage device 64, and recorded in the correction power source IC of the respective organic EL panels. Thus, it is possible to perform corrections on the organic EL panels having different shapes between different slots.

As described above, in the present embodiment, the distribution of the luminance unevenness within the same lot does not change significantly between slots even when organic EL panels of different shapes are manufactured in the slot. Therefore, as in the above-described embodiment, the measurement of the light emission intensity in the inspection process has only to be performed only once, and it is possible to determine the correction value for all the slots by using the measurement.

In the present embodiment, inspecting one inspection mother substrate 4 in the inspection process allows organic EL panels of different shapes between slots to be manufactured in the same lot. Therefore, there is no need to inspect luminance unevenness for each type of the organic EL panel, and various types of organic EL panels can be more easily manufactured.

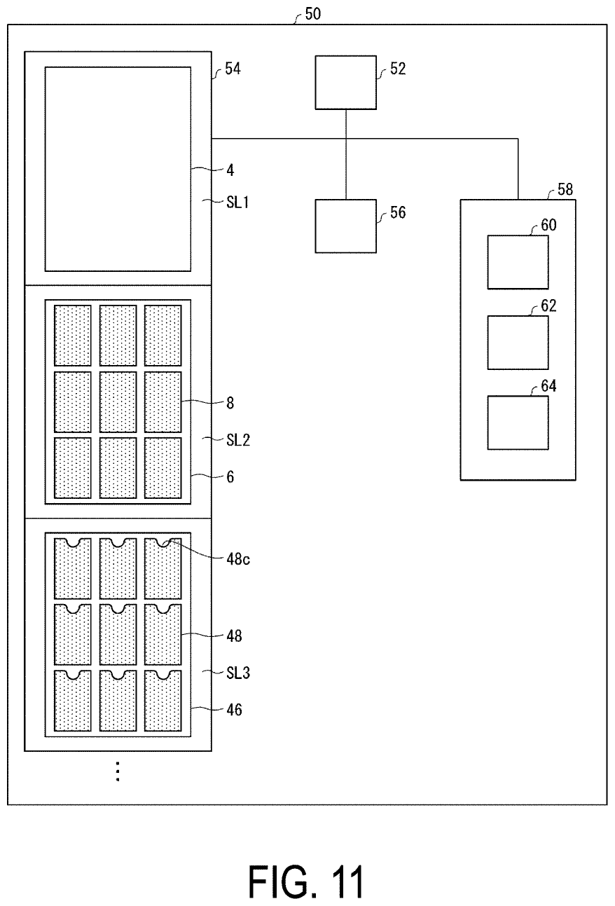

In addition, as a modified example, as illustrated in FIG. 11, the manufacturing apparatus 50 may manufacture a variant organic EL panel 48 with a notch portion 48c on the manufacturing mother substrate 46. Also in this case, the light emission voltage for each organic EL panel 48 can be corrected by the same method as described above. Thus, in the present embodiment, it is also possible to manufacture a display panel of a variant panel different from a rectangle shape.

### Supplement

A method for manufacturing a display panel of the first aspect includes:

an inspection mother substrate manufacturing step of manufacturing an inspection mother substrate including a plurality of inspection elements;

a manufacturing mother substrate manufacturing step of manufacturing a plurality of manufacturing mother substrates including a plurality of display panels including a light emitting element;

a measurement step of measuring distribution of light emission intensity from the plurality of inspection elements;

a calculation step of calculating a correction value of a light emission voltage for each of the display panels according to the distribution; and

a correction step of correcting the light emission voltage of the light emitting element of each of the display panels based on the correction value.

In the second aspect, the correction value is determined from a relationship between film thickness distribution of the manufacturing mother substrates and the light emission intensity of the inspection elements.

In the third aspect, in each of all the manufacturing mother substrates, the display panel to be manufactured is identical.

In the fourth aspect, in each of all the manufacturing mother substrates, the identical correction is performed on the display panels to be manufactured at an identical position.

In the fifth aspect, in at least one of the manufacturing mother substrates, a display panel to be manufactured is different from a display panel in the other manufacturing mother substrates.

In the sixth aspect, the manufacturing mother substrate manufacturing step includes, for each of the manufacturing mother substrates, recording information about a shape and an arrangement of the manufacturing mother substrates and a shape and an arrangement of the display panels in a substrate information storage device, and the measurement step includes recording the distribution in a distribution storage device.

In the seventh aspect, the calculation step includes determining, for each of the display panels, a difference between an average of the light emission intensity from the inspection elements corresponding to each of the manufacturing mother substrates and an average of the light emission intensity from the inspection elements corresponding to each of the display panels based on information recorded in the distribution storage device and the substrate information storage device, and includes determining the correction value for each of the display panels from the difference.

In the eighth aspect, the correction value is recorded in a correction value storage device.

In the ninth aspect, the correction value recorded into the correction value storage device is recorded in each of the display panels.

In the tenth aspect, the inspection elements are arranged on the inspection mother substrate in a matrix shape.

In the eleventh aspect, the inspection elements include a plurality of sub-elements and the sub-elements emit light of a color corresponding to each subpicture element of the light emitting element.

In the twelfth aspect, the inspection mother substrate is identical to any one of the manufacturing mother substrates, and the measurement is performed with the light emitting element as the inspection elements.

In the thirteenth aspect, the display panels are variant panels of a shape different from a rectangular shape.

The apparatus for manufacturing a display panel of the fourteenth aspect includes:

a substrate manufacturing device configured to manufacture an inspection mother substrate including

a plurality of inspection elements, and

a plurality of manufacturing mother substrates including a plurality of display panels including a light emitting element;

a measuring device configured to measure a distribution of light emission intensity from the plurality of inspection elements; and

a storage device configured to calculate a correction value of a light emission voltage of the light emitting element for each of the display panels corresponding to the distribution, to store the correction value, and to record the correction value into each of the display panels.

In the fifteenth aspect, the storage device includes a substrate information storage device in which information about a shape and an arrangement of the manufacturing mother substrates and a shape and an arrangement of the display panels is recorded for each of the manufacturing mother substrates.

In the sixteenth aspect, the storage device includes a distribution storage device in which the distribution is recorded.

In the seventeenth aspect, the storage device includes a correction value storage device in which the correction value is recorded.

The present disclosure is not limited to each of the embodiments stated above, and various modifications may be implemented within a range not departing from the scope of the claims. Embodiments obtained by appropriately combining technical approaches stated in each of the different embodiments also fall within the scope of the technology of the disclosure. Moreover, novel technical features may be formed by combining the technical approaches stated in each of the embodiments.

### REFERENCE SIGNS LIST

4 Inspection mother substrate
6, 42, 46 Manufacturing mother substrate
8, 44, 48 Organic EL panel
12 Light emitting element
14R⋅G⋅B Subpicture element
30 Inspection element
50 Manufacturing apparatus
52 Controller
54 Substrate manufacturing device
56 Measuring device
58 Storage device
60 Distribution storage device
62 Substrate information storage device
64 Correction value storage device

1. A method for manufacturing a display panel, the method comprising:
an inspection mother substrate manufacturing step of manufacturing an inspection mother substrate including a plurality of inspection elements;
a manufacturing mother substrate manufacturing step of manufacturing a plurality of manufacturing mother substrates including a plurality of display panels including a light emitting element;
a measurement step of measuring distribution of light emission intensity from the plurality of inspection elements;
a calculation step of calculating a correction value of a light emission voltage for each of the display panels according to the distribution; and
a correction step of correcting the light emission voltage of the light emitting element of each of the display panels based on the correction value.

2. The method for manufacturing a display panel according to claim 1,
wherein the correction value is determined from a relationship between film thickness distribution of the manufacturing mother substrates and the light emission intensity of the inspection elements.

3. The method for manufacturing a display panel according to claim 1,
wherein in each of all the manufacturing mother substrates, the display panel to be manufactured is identical.

4. The method for manufacturing a display panel according to claim 3, further comprising:
in each of all the manufacturing mother substrates, performing the identical correction on the display panels to be manufactured at an identical position.

5. The method for manufacturing a display panel according to claim 1,
wherein in at least one of the manufacturing mother substrates, a display panel to be manufactured is different from a display panel in the other manufacturing mother substrates.

6. The method for manufacturing a display panel according to claim 1,
wherein the manufacturing mother substrate manufacturing step includes, for each of the manufacturing mother substrates, recording information about a shape and an arrangement of the manufacturing mother substrates and a shape and an arrangement of the display panels in a substrate information storage device, and
the measurement step includes recording the distribution in a distribution storage device.

7. The method for manufacturing a display panel according to claim 6,
wherein the calculation step includes determining, for each of the display panels, a difference between an average of the light emission intensity from the inspection elements corresponding to each of the manufacturing mother substrates and an average of the light emission intensity from the inspection elements corresponding to each of the display panels based on information recorded in the distribution storage device and the substrate information storage device, and includes determining the correction value for each of the display panels from the difference.

8. The method for manufacturing a display panel according to claim 1, further comprising:
recording the correction value in a correction value storage device.

9. The method for manufacturing a display panel according to claim 8, further comprising:
recording the correction value written into the correction value storage device in each of the display panels.

10. The method for manufacturing a display panel according to claim 1,
wherein the inspection elements are arranged on the inspection mother substrate in a matrix shape.

11. The method for manufacturing a display panel according to claim 1,
wherein the inspection elements include a plurality of sub-elements and the sub-elements emit light of a color corresponding to each subpicture element of the light emitting element.

12. The method for manufacturing a display panel according to claim 1,
wherein the inspection mother substrate is identical to any one of the manufacturing mother substrates, and the measurement is performed with the light emitting element as the inspection elements.

13. The method for manufacturing a display panel according to claim 1,
wherein the display panels are variant panels of a shape different from a rectangular shape.

14. An apparatus configured to manufacture a display panel, the apparatus comprising:
a substrate manufacturing device configured to manufacture an inspection mother substrate including a plurality of inspection elements, and a plurality of manufacturing mother substrates including a plurality of display panels including a light emitting element;
a measuring device configured to measure a distribution of light emission intensity from the plurality of inspection elements; and
a storage device configured to calculate a correction value of a light emission voltage of the light emitting element for each of the display panels corresponding to the distribution, to store the correction value, and to record the correction value into each of the display panels.

15. The apparatus for manufacturing a display panel according to claim 14,
wherein the storage device includes a substrate information storage device in which information about a shape and an arrangement of the manufacturing mother substrates and a shape and an arrangement of the display panels is recorded for each of the manufacturing mother substrates.

16. The apparatus for manufacturing a display panel according to claim 14,
wherein the storage device includes a distribution storage device in which the distribution is recorded.

17. The apparatus for manufacturing a display panel according to claim 14,
wherein the storage device includes a correction value storage device in which the correction value is recorded.
